(19) United States
(12) Patent Application Publication
(10) Pub. No.: US 2026/0305024 A1
(43) Pub. Date: Oct. 1, 2026

(54) LIGHT EMITTING ELEMENT, DISPLAY DEVICE AND TILING DISPLAY DEVICE

(71) Applicant: LG Display Co., Ltd., Seoul (KR)

(72) Inventors: ChangBae PARK, Goyang-si (KR); Seokho SHIM, Paju-si (KR)

(21) Appl. No.: 19/415,710

(22) Filed: Dec. 10, 2025

(30) Foreign Application Priority Data
Mar. 31, 2025 (KR) 10-2025-0041614

(51) Int. Cl. H10H 20/855; H10H 20/821; H10H 20/831

(52) U.S. Cl. CPC H10H 20/855; H10H 20/821; H10H 20/831

(57) ABSTRACT

A light emitting element includes a first semiconductor layer, an light emitting layer disposed on one side of the first semiconductor layer, a second semiconductor layer disposed on one side of the light emitting layer, and a light shielding layer disposed to surround a side surface of the light emitting layer and including a black material.

### CROSS REFERENCE TO RELATED APPLICATION

This application claims priority from and the benefit of Korean Patent Application No. 10-2025-0041614, filed on Mar. 31, 2025, which is hereby incorporated by reference for all purposes as if fully set forth herein.

### BACKGROUND

### Field

Embodiments of the invention relate generally to a light emitting element and a display device including the same, and more particularly, without limitation, to a light emitting element with improved display quality and a display device including the same.

### Discussion of the Background

Display devices have been widely used in a variety of applications, including computer monitors and televisions, and personal portable devices. Research is being conducted on display devices with larger active area and reduced overall size and weight.

In addition, recently, a display device including a light emitting diode (LED) has attracted attention as a next-generation display device. Since the LED is formed of an inorganic material rather than an organic material, it can provide improved reliability and a relatively longer lifespan compared to a liquid crystal display device or an organic light emitting display device. Further, the LED may exhibit fast lighting speed, high luminous efficiency, and an enhanced impact resistance, thereby offering better stability and enabling the display of images with high luminance.

The above information disclosed in this Background section is only for understanding of the background of the inventive concepts, and, therefore, it may contain information that does not constitute prior art.

### SUMMARY

Embodiments of the invention provide a light emitting element having a uniform light emitting characteristic and a display device including the same.

Embodiments of the invention provide a light emitting element in which a deviation in light emitting characteristics is minimized and a display device including the same.

Additional features of the inventive concepts will be set forth in the description which follows, and in part will be apparent from the description, or may be learned by practice of the inventive concepts.

According to embodiments of the invention, a light emitting element includes a first semiconductor layer, a light emitting layer disposed on one side of the first semiconductor layer, a second semiconductor layer disposed on one side of the light emitting layer, and a light shielding layer disposed to surround a side surface of the light emitting layer and including a black material.

The light emitting element may further include a passivation film disposed to surround the side surfaces of the first semiconductor layer, the light emitting layer, and the second semiconductor layer. The light shielding layer may be disposed on the passivation film.

The light emitting element may further include a passivation film disposed to surround side surfaces of the first semiconductor layer, the light emitting layer, the second semiconductor layer, and the light shielding layer.

The light shielding layer may be disposed to extend to cover at least a portion of side surfaces of the first semiconductor layer and the second semiconductor layer.

The light emitting element may further include a first electrode disposed on the first semiconductor layer and a second electrode disposed on the second semiconductor layer. The light shielding layer may be disposed to extend to cover at least a part of side surfaces of the first electrode and the second electrode. The light shielding layer may be disposed on any one side surface of both side surfaces of the first electrode and any one side surface of both side surfaces of the second electrode.

The light emitting element may further include a first electrode disposed below the first semiconductor layer and a second electrode disposed below the second semiconductor layer. The light shielding layer may be disposed to cover at least a part of side surfaces of the first electrode and the second electrode. The light shielding layer may be disposed on any one side surface of both side surfaces of the first electrode and any one side surface of both side surfaces of the second electrode.

The light emitting element may further include a first electrode disposed below the first semiconductor layer and a second electrode disposed on the second semiconductor layer. The light shielding layer may be disposed to extend to cover at least a part of side surfaces of the first electrode and the second electrode. The light shielding layer may be disposed on both side surfaces of the first electrode and both side surfaces of the second electrode.

According to embodiments of the invention, a display device includes a substrate on which a plurality of sub-pixels is defined, a plurality of transistors disposed on the substrate, and a plurality of light emitting elements disposed in each of the plurality of sub-pixels on the plurality of transistors. Each of the plurality of light emitting elements includes a first semiconductor layer, a light emitting layer disposed on one side of the first semiconductor layer, a second semiconductor layer disposed on one side of the light emitting layer, and a light shielding layer disposed to surround a side surface of the light emitting layer and including a black material.

Each of the plurality of light emitting elements may further include a passivation film disposed to surround side surfaces of the first semiconductor layer, the light emitting layer, and the second semiconductor layer. The light shielding layer may be disposed on the passivation film.

The display device may further include a planarization layer disposed on the plurality of transistors and surrounding the plurality of light emitting elements. The light shielding layer may be in contact with the planarization layer. The plurality of light emitting elements may be a lateral type, flip-chip type, or vertical type light emitting element.

Each of the plurality of light emitting elements may further include a passivation film disposed to surround side surfaces of the first semiconductor layer, the light emitting layer, the second semiconductor layer, and the light shielding layer.

The light shielding layer may be disposed to extend to cover at least a portion of side surfaces of the first semiconductor layer and the second semiconductor layer.

Each of the plurality of light emitting elements may further include a first electrode disposed on the first semiconductor layer and a second electrode disposed on the second semiconductor layer. The light shielding layer may be disposed to cover at least a part of side surfaces of the first electrode and the second electrode. The light shielding layer may be disposed on any one side surface of both side surfaces of the first electrode and any one side surface of both side surfaces of the second electrode.

Each of the plurality of light emitting elements may further include a first electrode disposed below the first semiconductor layer and a second electrode disposed below the second semiconductor layer. The light shielding layer may be disposed to cover at least a part of side surfaces of the first electrode and the second electrode. The light shielding layer may be disposed on any one side surface of both side surfaces of the first electrode and any one side surface of the second electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIGS. 1A and 1B are cross-sectional views of a light emitting element according to an embodiment of the invention.

FIG. 2 is a cross-sectional view of a light emitting element according to another embodiment of the invention.

FIG. 3 is a cross-sectional view of a light emitting element according to yet another embodiment of the invention.

FIG. 4 is a cross-sectional view of a light emitting element according to yet another embodiment of the invention.

FIG. 5 is a cross-sectional view of a light emitting element according to yet another embodiment of the invention.

FIG. 6 is a cross-sectional view of a light emitting element according to yet another embodiment of the invention.

FIG. 7 is a schematic block diagram of a display device according to an embodiment of the invention.

FIG. 8A is a partial cross-sectional view of a display device according to an embodiment of the invention.

FIG. 8B is a perspective view of a tiling display device according to an embodiment of the invention.

FIG. 9 is a cross-sectional view of a display device according to an embodiment of the invention.

FIG. 10 is a cross-sectional view of a display device according to another embodiment of the invention.

FIG. 11 is a cross-sectional view of a display device according to yet another embodiment of the invention.

FIG. 12 is a cross-sectional view of a display device according to yet another embodiment of the invention.

FIG. 13 is a cross-sectional view of a display device according to yet another embodiment of the invention.

FIG. 14 is a cross-sectional view of a display device according to yet another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

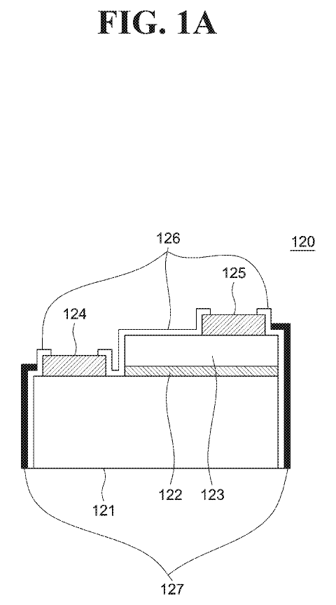

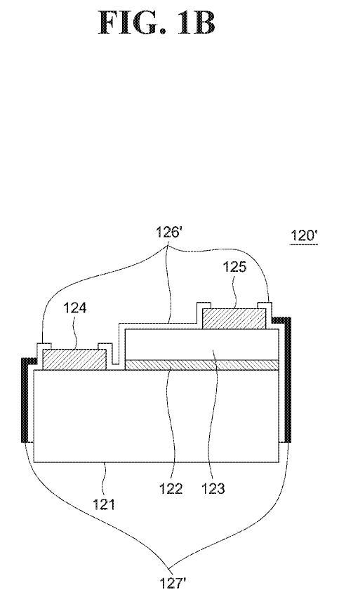

FIGS. 1A and 1B are cross-sectional views of a light emitting element according to embodiments of the invention. FIG. 1A illustrates a case in which the passivation film 126 and the light shielding layer 127 are not torn when the light emitting element 120 is separated on the wafer. FIG. 1B illustrates a case in which the passivation film 126' and the light shielding layer 127' are torn when the light emitting element 120' is separated on the wafer. The light emitting element 120 of FIG. 1A and the light emitting element 120' of FIG. 1B are lateral type light emitting elements.

Referring to FIGS. 1A and 1B, a light emitting element 120 and 120’ according to embodiments of the invention includes a first semiconductor layer 121, a light emitting layer 122, a second semiconductor layer 123, a first electrode 124, a second electrode 125, passivation films 126 and 126’, and light shielding layers 127 and 127’.

The first semiconductor layer 121 and the second semiconductor layer 123 may be layers formed by doping n-type and p-type impurities into a specific material. For example, the first semiconductor layer 121 and the second semiconductor layer 123 may be layers doped with n-type and p-type impurities into a material such as gallium nitride (GaN), indium aluminum phosphide (InAlP), or gallium arsenide (GaAs), without being limited thereto. Further, the p-type impurity may be magnesium (Mg), zinc (Zn), beryllium (Be), and the like, and the n-type impurity may be silicon (Si), germanium (Ge), tin (Sn), and the like, but not limited thereto.

The light emitting layer 122 may be disposed between the first semiconductor layer 121 and the second semiconductor layer 123. The light emitting layer 122 may receive holes and electrons from the first semiconductor layer 121 and the second semiconductor layer 123 to emit light.

The light emitting layer 122 may be formed by a single layer or a multi-quantum well (MQW) structure, and for example, may be formed of indium gallium nitride (InGaN) or gallium nitride (GaN), without being limited thereto.

The first electrode 124 may be disposed on the first semiconductor layer 121. For example, the first semiconductor layer 121 may be a semiconductor layer doped with an n-type impurity, and the first electrode 124 may be a cathode, without being limited thereto. The first electrode 124 may be disposed on an upper surface of the first semiconductor layer 121 exposed from the light emitting layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 may be disposed on the second semiconductor layer 123. The second semiconductor layer 123 may be a semiconductor layer doped with a p-type impurity, and the second electrode 125 may be an anode, without being limited thereto. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, without being limited thereto.

The passivation films 126 and 126' may be disposed to surround the first semiconductor layer 121, the light emitting layer 122, the second semiconductor layer 123, the first electrode 124, and the second electrode 125. The passivation films 126 and 126’ may be formed of an insulating material and protect the first semiconductor layer 121, the light emitting layer 122, and the second semiconductor layer 123. For example, the passivation films 126 and 126’ may be formed of translucent epoxy, aluminum oxide (Al₂O₃), silicon oxide (SiOx), or silicon nitride (SiNx), but are not limited thereto. Further, contact holes exposing the first electrode 124 and the second electrode 125 may be formed in the passivation films 126 and 126’.

In some embodiments of the invention according to FIG. 1A, one end of the passivation film 126 may be disposed on the same plane as one end of the first semiconductor layer 121.

In other embodiments according to FIG. 1B, the passivation film 126’ may be disposed to partially expose a lower edge of the first semiconductor layer 121. For example, during the process of separating the light emitting element 120' from the wafer, a part of the passivation film 126' is torn off at the lower edge of the light emitting element 120' to expose a part of the first semiconductor layer 121 at the lower edge of the light emitting element 120', but embodiments of the invention not limited thereto.

Referring to FIGS. 1A and 1B together, the light shielding layers 127 and 127’ may be disposed on the passivation films 126 and 126’. The light shielding layers 127 and 127’ may be disposed on the side surfaces of the light emitting elements 120 and 120’ to absorb non-uniform light emitted to the side surface. For example, the outer surfaces of the light emitting elements 120 and 120’ may be formed differently for each light emitting element 120 and 120’ due to a process or the like. Accordingly, light emitted from the outer peripheral area of the light emitting elements 120 and 120' may vary for each light emitting element 120 and 120'. In particular, the light emitted from the side surface may have different controllability compared to the front light. Therefore, the light shielding layers 127 and 127' may be disposed on the side surface of the outer peripheral area of the light emitting elements 120 and 120' to absorb non-uniform light emitted from the side surface, thereby improving uniformity in the light emitting characteristics of the light emitting elements 120 and 120'. The light shielding layers 127 and 127’ may also be disposed to cover at least a portion of the side surface of the light emitting layer 122, but embodiments of the invention are not limited thereto. For example, the light shielding layers 127 and 127’ may extend to surround at least a portion of side surfaces of the first semiconductor layer 121, the second semiconductor layer 123, the first electrode 124, the second electrode 125, and the passivation films 126 and 126’ as well as the light emitting layer 122. The light shielding layers 127 and 127’ may also be disposed to cover at least a portion of the side surface of the passivation films 126 and 126’, without being limited thereto. Alternatively, the light shielding layers 127 and 127’ may be omitted depending on the design.

The light shielding layers 127 and 127’ may be disposed to enclose the side surface of the outer surfaces of the light emitting elements 120 and 120’. In this case, when the light emitting elements 120 and 120’ are of a lateral type, the light shielding layers 127 and 127’ may be disposed to enclose one side surface of the first electrode 124. For example, as illustrated in FIGS. 1A and 1B, the light shielding layers 127 and 127’ may be disposed on the left side surface of the first electrode 124 and may not be disposed on the right side surface of the first electrode 124, but embodiments of the invention are not limited thereto.

In a similar manner, the light shielding layers 127 and 127’ may be disposed to enclose one side surface of the second electrode 125. For example, as illustrated in FIGS. 1A and 1B, the light shielding layers 127 and 127’ may be disposed on the right side surface of the second electrode 125 and may not be disposed on the left side surface of the second electrode 125, but embodiments of the invention are not limited thereto.

The light shielding layers 127 and 127’ may expose at least a portion of the passivation films 126 and 126’. For example, the passivation films 126 and 126’ may be disposed up to upper surfaces of the first electrode 124 and the second electrode 125, while the light shielding layers 127 and 127’ may be disposed up to side surfaces of the first electrode 124 and the second electrode 125. Accordingly, the light shielding layers 127 and 127’ may expose at least a portion of the passivation films 126 and 126’ disposed on side surfaces of the first electrode 124 and the second electrode 125, but embodiments of the invention are not limited thereto.

The light shielding layers 127 and 127’ may include a black material capable of absorbing light. For example, the black material may be formed of a base resin and a black material, but is not limited thereto.

The light shielding layers 127 and 127’ may be formed on a wafer. Accordingly, the light emitting elements 120 and 120’ including the light shielding layers 127 and 127’ may be separated from the wafer to be transferred to the display panel, but embodiments of the invention are not limited thereto.

In some embodiments, as illustrated in FIG. 1A, one end of the light shielding layer 127 may be disposed on the same plane as one end of the first semiconductor layer 121.

In other embodiments, as illustrated in FIG. 1B, the light shielding layer 127’ may be disposed to partially expose the lower edge of the first semiconductor layer 121 together with the passivation film 126’. For example, as described above, during the process of separating the wafer and the light emitting element 120', a part of the light shielding layer 127' is torn along with the passivation film 126' at the lower edge of the light emitting element 120' to expose a part of the first semiconductor layer 121' at the lower edge of the light emitting element 120', but embodiments of the invention not limited thereto.

Although FIG. 1B illustrates that ends of the light shielding layer 127’ and the passivation film 126’ are disposed on the same plane, embodiments of the invention are not limited thereto. For example, depending on the degree of tear of the passivation film 126’ and the light shielding layer 127’, the end of the light shielding layer 127’ may be disposed higher than the end of the passivation film 126’. As such, the light shielding layer 127’ may be disposed to expose the passivation film 126’ at a lower side. Alternatively, the end of the passivation film 126’ may be disposed higher than the end of the light shielding layer 127’, and embodiments of the invention are not limited to the configuration illustrated in the drawings.

To achieve uniform display quality of a display device, it may be desirable for the light emitting characteristics such as luminance of a plurality of light emitting elements disposed in the display device to be relatively uniform. However, variations in the manufacturing process may cause differences in the shapes of the plurality of light emitting elements disposed in the display device, which may result in variations in the light emitting characteristics. In particular, variations in forming the outer periphery of the light emitting element for each light emitting element may cause non-uniform light emission. Accordingly, the deviation of the light emitting characteristics between the light emitting elements may be intensified, which may affect display uniformity and quality. Therefore, in order to implement a uniform display quality, it may be desirable to compensate for such a deviation. For example, the side surface of the display device may have a wider viewing angle range than the front surface, and therefore compensation for the deviation of the visibility of the side surface from the front surface may vary.

Meanwhile, a tiling display device having a large screen may be implemented by electrically connecting a plurality of display devices. In the case of a tiling display device in which a plurality of display devices are electrically connected as described above, it may be advantageous to reduce or minimize a deviation in display quality between a plurality of display devices as well as a deviation in display quality within one display device. Therefore, it may become noticeable in a tiling display device having a deviation according to such side light.

Accordingly, the light emitting elements 120 and 120’ according to the embodiment of invention may include light shielding layers 127 and 127’ which are disposed on the side surfaces and include a black material. Specifically, the light shielding layers 127 and 127’ may be disposed to cover a side surface of the light emitting layer 122 in an outer peripheral area of the light emitting element 120 and absorb light leaking from the side surface of the light emitting layer 122. For example, the light shielding layers 127 and 127’ are disposed on the side surfaces of the light emitting elements 120 and 120’ to absorb non-uniform light emitted to the side surfaces, thereby making the light emitting characteristics of the light emitting elements 120 and 120’ substantially uniform. The light shielding layers 127 and 127’ may also reduce or minimize a deviation of light emitting characteristics between the plurality of light emitting elements 120 and 120’. Accordingly, the display device including the light emitting elements 120 and 120’ according to an embodiment of the invention may implement a substantially uniform image, and a tiling display device including multiple electrically connected display devices according to an embodiment of the invention may also implement a uniform image. Further, the display device including the light emitting elements 120 and 120’ according to an embodiment of the invention and the tiling display device including the same may provide improved display quality.

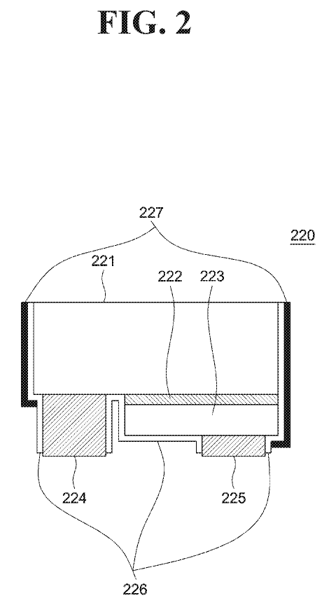

FIG. 2 is a cross-sectional view of a light emitting element according to another embodiment of the invention. The light emitting element 220 of FIG. 2 is a flip-chip type light emitting element, which differs from the light emitting element 120' of FIG. 1A and the light emitting element 120' of FIG. 1B.

Referring to FIG. 2, a light emitting element 220 according to another embodiment of the invention include a first semiconductor layer 221, a light emitting layer 222, a second semiconductor layer 223, a first electrode 224, a second electrode 225, a passivation film 226, and a light shielding layer 227.

The first semiconductor layer 221 and the second semiconductor layer 223 may be layers formed by doping n-type and p-type impurities into a specific material. For example, the first semiconductor layer 221 and the second semiconductor layer 223 may be layers doped with n-type and p-type impurities into a material such as gallium nitride (GaN), indium aluminum phosphide (InAlP), or gallium arsenide (GaAs), without being limited thereto. Further, the p-type impurity may be magnesium (Mg), zinc (Zn), beryllium (Be), and the like, and the n-type impurity may be silicon (Si), germanium (Ge), tin (Sn), and the like, but not limited thereto.

The light emitting layer 222 may be disposed between the first semiconductor layer 221 and the second semiconductor layer 223. The light emitting layer 222 may emit light by receiving holes and electrons from the first semiconductor layer 221 and the second semiconductor layer 223.

The light emitting layer 222 may be formed by a single layer or a multi-quantum well (MQW) structure, and for example, may be formed of indium gallium nitride (InGaN) or gallium nitride (GaN), without being limited thereto.

The first electrode 224 may be disposed below the first semiconductor layer 221. The first semiconductor layer 221 may be a semiconductor layer doped with an n-type impurity, and the first electrode 224 may be a cathode, without being limited thereto. The first electrode 224 may be disposed on a lower surface of the first semiconductor layer 221 exposed from the light emitting layer 222 and the second semiconductor layer 223. The first electrode 224 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 225 may be disposed below the second semiconductor layer 223. The second semiconductor layer 223 may be a semiconductor layer doped with a p-type impurity, and the second electrode 225 may be an anode, without being limited thereto. The second electrode 225 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

A passivation film 226 surrounding the first semiconductor layer 221, the light emitting layer 222, the second semiconductor layer 223, the first electrode 224, and the second electrode 225 may be disposed. The passivation film 226 may be formed of an insulating material to protect the first semiconductor layer 221, the light emitting layer 222, and the second semiconductor layer 223. For example, the passivation film 226 may be formed of translucent epoxy, aluminum oxide (Al₂O₃), silicon oxide (SiOx), or silicon nitride (SiNx), but is not limited thereto. Further, a contact hole which exposes the first electrode 224 and the second electrode 225 may be formed in the passivation film 226.

FIG. 2 illustrates that one end of the passivation film 226 may be disposed on the same plane as one end of the first semiconductor layer 221. However, the embodiments of the invention are not limited thereto. In some embodiments, the passivation film 226 may be disposed to partially expose the upper edge of the first semiconductor layer 221. For example, during the process of separating the light emitting element 220 from the wafer, a part of the passivation film 226 is torn off at the upper edge of the light emitting element 220 to expose a part of the first semiconductor layer 221 of the upper edge of the light emitting element 220, but embodiments of the invention are not limited thereto.

A light shielding layer 227 may be disposed on the passivation film 226. The light shielding layer 227 may be disposed on a side surface of the light emitting element 220 to absorb non-uniform light emitted to the side surface. For example, the outer surface of the light emitting element 220 may be formed differently for each light emitting element 220 due to a process or the like. Accordingly, in the outer region of the light emitting element 220, light emission may vary for each light emitting element 220. In particular, the light emitted from the side surface may have different controllability compared to the front light. Accordingly, the light shielding layer 227 may be disposed on the side surface in the outer area of the light emitting element 220 to absorb non-uniform light emitted from the side surface, thereby helping improve uniformity in the light emitting characteristics of the light emitting element 220. The light shielding layer 227 may also be disposed to cover at least a portion of the side surface of the light emitting layer 222, but is not limited thereto. For example, the light shielding layer 227 may extend to enclose at least a portion of side surfaces of the first semiconductor layer 221, the second semiconductor layer 223, the first electrode 224, the second electrode 225, and the passivation film 226 as well as the light emitting layer 222.

The light shielding layer 227 is disposed to enclose a side surface of the outer peripheral surface of the light emitting element 220. In this case, since the light emitting element 220 according to another embodiment of the invention is a flip-chip type, the light shielding layer 227 may be disposed to surround any one of both side surfaces of the first electrode 224. For example, as illustrated in FIG. 2, the light shielding layer 227 may be disposed on the left side surface of the first electrode 224 and may not be disposed on the right side surface, but embodiments of the invention are not limited thereto.

In a similar manner, the light shielding layer 227 may be disposed to enclose one of both side surfaces of the second electrode 225. For example, as illustrated in FIG. 2, the light shielding layer 227 may be disposed on the right side surface of the second electrode 225 and not on the left side surface, but embodiments of the invention are not limited thereto.

The light shielding layer 227 may expose at least a portion of the passivation film 226. For example, the passivation film 226 may be disposed up to the lower surfaces of the first electrode 224 and the second electrode 225, while the light shielding layer 227 may be disposed up to the side surfaces of the first electrode 224 and the second electrode 225. Accordingly, the light shielding layer 227 may expose at least a portion of the passivation film 226 disposed on side surfaces of the first electrode 224 and the second electrode 225, but embodiments of the invention are not limited thereto.

The light shielding layer 227 may include a black material capable of absorbing light. For example, the black material may be formed of a base resin and a black material, but is not limited thereto.

The light shielding layer 227 may be formed on a wafer. Accordingly, the light emitting element 220 including the light shielding layer 227 may be separated from the wafer and transferred to the display panel, but embodiments of the invention are not limited thereto.

Although FIG. 2 illustrates that one end of the light shielding layer 227 may be disposed on the same plane as one end of the first semiconductor layer 221, embodiments of the invention are not limited thereto. In some embodiments, the light shielding layer 227 may be disposed to partially expose the upper edge of the first semiconductor layer 221 together with the passivation film 226. For example, as described above, in the process of separating the light emitting element 220 from the wafer, a part of the light shielding layer 227 is torn along with the passivation film 226 at the upper edge of the light emitting element 220 to expose a part of the first semiconductor layer 221 of the upper edge of the light emitting element 220, but embodiments of the invention are not limited thereto.

The light emitting element 220 according to another embodiment of the invention may include a light shielding layer 227 which is disposed on a side surface of the light emitting element 220 and includes a black material. Specifically, the light shielding layer 227 may be disposed to cover the side surface of the light emitting layer 222 in the outer peripheral area of the light emitting element 220 and absorb non-uniform light emitted to the side surface to render the light emitting characteristics of the light emitting element 220 substantially uniform. For example, the light shielding layer 227 may reduce or minimize a deviation in light emitting characteristics between the plurality of light emitting elements 220. Accordingly, the display device including the light emitting element 220 according to another embodiment of the invention may implement a substantially uniform image. Accordingly, a tiling display device including a plurality of display devices including the light emitting element 220 and electrically connected to one another according to another embodiment of the invention may also implement a substantially uniform image. Further, the display device including the light emitting element 220 according to another embodiment of the invention and the tiling display device including the plurality of display devices electrically connected to one another may provide improved display quality.

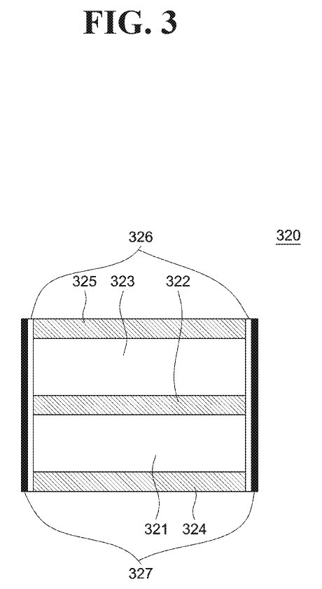

FIG. 3 is a cross-sectional view of a light emitting element according to yet another embodiment of the invention. As compared to the light emitting element 120 of FIG. 1A and the light emitting element 120' of FIG. 1B, the light emitting element 320 of FIG. 3 is a vertical chip type light emitting element.

Referring to FIG. 3, a light emitting element 320 according to yet another embodiment of the invention includes a first semiconductor layer 321, a light emitting layer 322, a second semiconductor layer 323, a first electrode 324, a second electrode 325, a passivation film 326, and a light shielding layer 327.

The first semiconductor layer 321 and the second semiconductor layer 323 may be layers formed by doping n-type and p-type impurities into a specific material. For example, the first semiconductor layer 321 and the second semiconductor layer 323 may be layers doped with n-type and p-type impurities into a material such as gallium nitride (GaN), indium aluminum phosphide (InAlP), or gallium arsenide (GaAs), without being limited thereto. Further, the p-type impurity may be magnesium (Mg), zinc (Zn), beryllium (Be), and the like, and the n-type impurity may be silicon (Si), germanium (Ge), tin (Sn), and the like, but not limited thereto.

The light emitting layer 322 may be disposed between the first semiconductor layer 321 and the second semiconductor layer 323. The light emitting layer 322 may receive holes and electrons from the first semiconductor layer 321 and the second semiconductor layer 323 to emit light.

The light emitting layer 322 may be formed as a single layer or a multi-quantum well (MQW) structure, and for example, may be formed of indium gallium nitride (InGaN) or gallium nitride (GaN), without being limited thereto.

The first electrode 324 may be disposed below the first semiconductor layer 321. The first semiconductor layer 321 may be a semiconductor layer doped with an n-type impurity, and the first electrode 324 may be a cathode, without being limited thereto. The first electrode 324 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 325 may be disposed on the second semiconductor layer 323. The second semiconductor layer 323 may be a semiconductor layer doped with a p-type impurity, and the second electrode 325 may be an anode. The second electrode 325 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, without being limited thereto.

A passivation film 326 may be disposed to surround the first semiconductor layer 321, the light emitting layer 322, the second semiconductor layer 323, the first electrode 324, and the second electrode 325. The passivation film 326 may be made of an insulating material to protect the first semiconductor layer 321, the light emitting layer 322, and the second semiconductor layer 323. For example, the passivation film 326 may be made of translucent epoxy, aluminum oxide (Al₂O₃), silicon oxide (SiOx), or silicon nitride (SiNx), but is not limited thereto.

Although FIG. 3 illustrates that the ends of the passivation film 326 may be disposed on the same plane as the end of the first semiconductor layer 321 and the end of the second semiconductor layer 323, embodiments of the invention are not limited thereto. The passivation film 326 may be disposed to expose a part of the lower edge of the first semiconductor layer 321 or the upper edge of the second semiconductor layer 323. For example, during the process of separating the wafer and the light emitting element 320, a part of the passivation film 326 is torn at the lower edge or the upper edge of the light emitting element 320 to expose a part of the first semiconductor layer 321 of the lower edge of the light emitting element 320 or a part of the second semiconductor layer 323 of the upper edge of the light emitting element 320, but embodiments of the invention are not limited thereto.

A light shielding layer 327 may be disposed on the passivation film 326. The light shielding layer 327 may be disposed on the side surface of the light emitting element 320 to absorb non-uniform light emitted to the side surface. For example, the outer surface of the light emitting element 320 may be formed differently for each light emitting element 320 due to a process or the like. Accordingly, in the outer region of the light emitting element 320, light emitted may vary for each light emitting element 320. In particular, the light emitted from the side surface may have different controllability compared to the front light. Therefore, light shielding layer 327 may be disposed on the side surface in the outer area of the light emitting element 320 to absorb non-uniform light emitted from the side surface, thereby helping improve uniformity in the light emitting characteristics of the light emitting element 320. The light shielding layer 327 may also be disposed to cover at least a portion of the side surface of the light emitting layer 322, but is not limited thereto. For example, the light shielding layer 327 may be disposed to extend to enclose at least a portion of side surfaces of the first semiconductor layer 321, the second semiconductor layer 323, the first electrode 324, the second electrode 325, and the passivation film 326 as well as the light emitting layer 322.

The light shielding layer 327 may be disposed to enclose a side surface of the outer surface of the light emitting element 320. In this case, since the light emitting element 320 according to yet another embodiment of the invention is of a vertical type, the light shielding layer 327 may be disposed to surround both side surfaces of the first electrode 324. In a similar manner, the light shielding layer 327 may be disposed to surround both side surfaces of the second electrode 325. The light shielding layer 327 may include a black material capable of absorbing light. For example, the black material may be made of a base resin and a black material, but is not limited thereto.

For example, the light shielding layer 327 may be formed on a wafer. Accordingly, the light emitting element 320 including the light shielding layer 327 may be separated from the wafer to be transferred to the display panel, but embodiments of the invention are not limited thereto.

FIG. 3 illustrates that the ends of the light shielding layer 327 may be disposed on the same plane as the end of the first semiconductor layer 321 and the end of the second semiconductor layer 323. However, embodiments of the invention are not limited thereto. The light shielding layer 327 may be disposed to partially expose the lower edge of the first semiconductor layer 321 or the upper edge of the second semiconductor layer 323 together with the passivation film 326. For example, as described above, during the process of separating the light emitting element 320 from the wafer, a part of the light shielding layer 327 is torn along with the passivation film 326 at the lower edge or the upper edge of the light emitting element 320 to expose a part of the first semiconductor layer 321 of the lower edge of the light emitting element 320 or a part of the second semiconductor layer 323 of the upper edge of the light emitting element 320, but embodiments of the invention are not limited thereto. The ends of the light shielding layer 327 may extend beyond the end of the first semiconductor layer 321 and the end of the second semiconductor layer 323, without being limited thereto. The ends of the light shielding layer 327 may also extend beyond the end of the first semiconductor layer 321 and the end of the second semiconductor layer 323 to be electrically in contact with a side surface of the first electrode 324 and the second electrode 325. Further, the ends of the light shielding layer 327 may be aligned with the upper end of the second electrode 325 and the lower end of the first electrode 324, without being limited thereto.

The light emitting element 320 according to yet another embodiment of the invention may include a light shielding layer 327 which is disposed on a side surface of the light emitting element 320 and includes a black material. Specifically, the light shielding layer 327 may be disposed to cover a side surface of the light emitting layer 322 in an outer peripheral area of the light emitting element 320 and absorb non-uniform light emitted to a side surface, thereby making the light emitting characteristics of the light emitting element 320 substantially uniform. For example, the light shielding layer 327 may reduce or minimize a deviation in light emitting characteristics between the plurality of light emitting elements 320. Accordingly, the display device including the light emitting element 320 according to yet another embodiment of the invention may implement a substantially uniform image, and a tiling display device including a plurality of display devices including the light emitting element 320 and electrically connected to one another according to yet another embodiment of the invention may also provide a substantially uniform image. Further, the display device including the light emitting element 320 according to yet another embodiment of the invention and the tiling display device including the plurality of display devices electrically connected to one another may provide improved display quality.

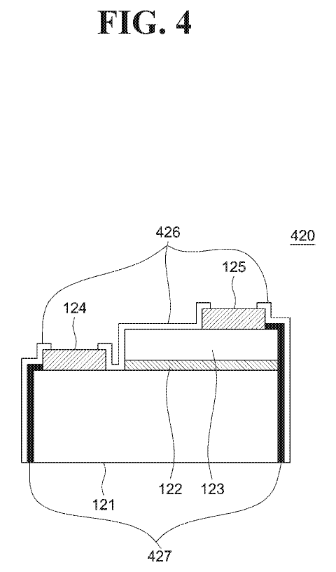

FIG. 4 is a cross-sectional view of a light emitting element according to yet another embodiment of the invention. Similar to the light emitting element 120 of FIG. 1A and the light emitting element 120' of FIG. 1B, the light emitting element 420 of FIG. 4 is a light emitting element of a lateral type. Only a passivation film 426 and a light shielding layer 427 are different from the light emitting element 120 of FIG. 1A and the light emitting element 120' of FIG. 1B, but other components are substantially the same, thus redundant descriptions will be omitted or briefly given.

Referring to FIG. 4, the light shielding layer 427 may be disposed to enclose side surfaces of the first semiconductor layer 121, the light emitting layer 122, the second semiconductor layer 123, the first electrode 124, and the second electrode 125.

The light shielding layer 427 may be disposed on the side surface of the light emitting element 420 to absorb non-uniform light emitted to the side surface. For example, the outer surface of the light emitting element 420 may be formed differently for each light emitting element 420 due to a process or the like. Accordingly, light emitted from the outer area of the light emitting element 420 may vary for each light emitting element 420. In particular, the light emitted from the side surface may have different controllability compared to the front light. Therefore, the light shielding layer 427 may be disposed on the side surface in the outer area of the light emitting element 420 to absorb non-uniform light emitted from the side surface, thereby helping improve uniformity in the light emitting characteristics of the light emitting element 420. The light shielding layer 427 may also be disposed to cover at least a portion of the side surface of the light emitting layer 122, but is not limited thereto. For example, the light shielding layer 427 may be disposed to extend to enclose at least a portion of side surfaces of the first semiconductor layer 121, the second semiconductor layer 123, the first electrode 124, and the second electrode 125 as well as the light emitting layer 122.

The passivation film 426 may be disposed on the light shielding layer 427 to surround the first semiconductor layer 121, the light emitting layer 122, the second semiconductor layer 123, the first electrode 124, the second electrode 125, and the light shielding layer 427.

The passivation film 426 may be formed of an insulating material to protect the first semiconductor layer 121, the light emitting layer 122, the second semiconductor layer 123, and the light shielding layer 427. For example, the passivation film 426 may be formed of translucent epoxy, aluminum oxide (Al₂O₃), silicon oxide (SiOx), or silicon nitride (SiNx), but is not limited thereto. Further, a contact hole exposing the first electrode 124 and the second electrode 125 may be formed in the passivation film 426.

FIG. 4 illustrates an example in which the passivation film 426 and the light shielding layer 427 are not torn when the light emitting element 420 is separated from the wafer as illustrated in FIG. 1A. However, as illustrated in FIG. 1B, when the passivation film 426 and the light shielding layer 427 are torn, the passivation film 426 and the light shielding layer 427 may be disposed to expose a lower edge of the first semiconductor layer 121.

The light emitting element 420 according to yet another embodiment of the invention may include a light shielding layer 427 which is disposed on a side surface of the light emitting element 420 and includes a black material. Specifically, the light shielding layer 427 is disposed to cover the side surface of the light emitting layer 122 in the outer peripheral area of the light emitting element 420 and absorb non-uniform light emitted to the side surface to make the light emitting characteristic of the light emitting element 420 substantially uniform. For example, the light shielding layer 427 may reduce or minimize a deviation in light emitting characteristics between the plurality of light emitting elements 420. Accordingly, the display device including the light emitting element 420 according to yet another embodiment of the invention may implement a substantially uniform image, and a tiling display device to which a plurality of display devices including the light emitting element 420 according to yet another embodiment of the invention are electrically connected may also implement a substantially uniform image. Further, the display device including a light emitting element 420 according to yet another embodiment of the invention and the tiling display device including a plurality of display devices electrically connected to one another provide improved display quality.

In particular, in the light emitting element 420 according to yet another embodiment of the invention, the passivation film 426 may be disposed on the light shielding layer 427. Specifically, the passivation film 426 may be disposed on the light shielding layer 427 to surround the light shielding layer 427 as well as the first semiconductor layer 121, the light emitting layer 122, the second semiconductor layer 123, the first electrode 124, and the second electrode 125. Accordingly, the passivation film 426 may protect the light shielding layer 427, and it may be possible to reduce or minimize the separation of the light shielding layer 427 or the penetration of impurities into the light shielding layer 427 during the process. For example, the passivation film 426 may be disposed to surround at least a portion of the light shielding layer 427, without being limited thereto. In addition, the passivation film 426 may be disposed to extend beyond the light shielding layer 427 to be electrically in contact with the first electrode 124 and the second electrode 125, without being limited thereto.

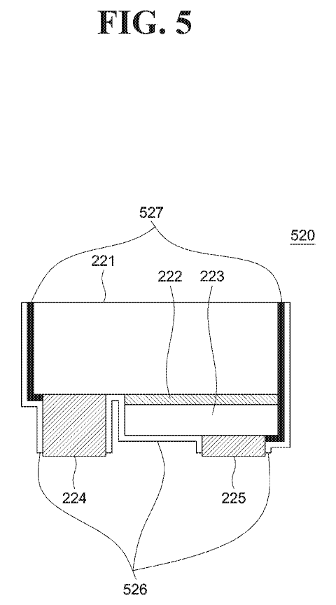

FIG. 5 is a cross-sectional view of a light emitting element according to yet another embodiment of the invention. The light emitting element 520 of FIG. 5 is a flip-chip type light emitting element like the light emitting element 220 of FIG. 2, and only a passivation film 526 and a light shielding layer 527 are different from the light emitting element 220 of FIG. 2, but other components are substantially the same, thus redundant descriptions will be omitted or briefly given.

Referring to FIG. 5, the light shielding layer 527 may be disposed to enclose side surfaces of the first semiconductor layer 221, the light emitting layer 222, the second semiconductor layer 223, the first electrode 224, and the second electrode 225.

The light shielding layer 527 may be disposed on the side surface of the light emitting element to absorb non-uniform light emitted to the side surface. For example, the outer surface of the light emitting element 520 may be formed differently for each light emitting element 520 due to process or the like. Accordingly, in the outer region of the light emitting element 520, the emitted light may vary for each light emitting element 520. In particular, the light emitted from the side surface may have different controllability compared to the front light. Therefore, the light shielding layer 527 may be disposed on the side surface in the outer area of the light emitting element 520 to absorb non-uniform light emitted from the side surface, thereby helping improve uniformity in the light emitting characteristics of the light emitting element 520. The light shielding layer 527 may also be disposed to cover at least a portion the side surface of the light emitting layer 222. However, the present disclosure is not limited thereto. For example, the light shielding layer 527 may be disposed to extend to enclose at least a portion of side surfaces of the first semiconductor layer 221, the second semiconductor layer 223, the first electrode 224, and the second electrode 225 as well as the light emitting layer 222.

The passivation film 526 may be disposed on the light shielding layer 527 to surround the first semiconductor layer 221, the light emitting layer 222, the second semiconductor layer 223, the first electrode 224, the second electrode 225, and the light shielding layer 527.

The passivation film 526 may be formed of an insulating material to protect the first semiconductor layer 221, the light emitting layer 222, the second semiconductor layer 223, and the light shielding layer 527. For example, the passivation film 526 may be formed of translucent epoxy, aluminum oxide (Al₂O₃), silicon oxide (SiOx), or silicon nitride (SiNx), but is not limited thereto. Further, a contact hole exposing the first electrode 224 and the second electrode 225 may be formed in the passivation film 526.

The light emitting element 520 according to yet another embodiment of the invention may include a light shielding layer 527 which is disposed on a side surface of the light emitting element and includes a black material Specifically, the light shielding layer 527 may be disposed to cover the side surface of the light emitting layer 222 in the outer peripheral area of the light emitting element 520 and absorb non-uniform light emitted to the side surface to make the light emitting characteristics of the light emitting element 520 substantially uniform. For example, the light shielding layer 527 may reduce or minimize a deviation in light emitting characteristics between the plurality of light emitting elements 520. Accordingly, the display device including the light emitting element 520 according to yet another embodiment of the invention may implement a substantially uniform image, and a tiling display device including a plurality of display devices including the light emitting element 520 electrically connected to one another according to yet another embodiment of the invention may also implement a substantially uniform image. Further, the display device including a light emitting element 520 according to yet another embodiment of the invention and the tiling display device including a plurality of display devices electrically connected to one another may provide improved display quality.

In particular, in the light emitting element 520 according to yet another embodiment of the invention, the passivation film 526 may be disposed on the light shielding layer 527. Specifically, the passivation film 526 may be disposed on the light shielding layer 527 to surround the light shielding layer 527 as well as the first semiconductor layer 221, the light emitting layer 222, the second semiconductor layer 223, the first electrode 224, and the second electrode 225. Accordingly, the passivation film 526 may protect the light shielding layer 527, and it may be possible to reduce or minimize the separation of the light shielding layer 527 or the penetration of impurities into the light shielding layer 527 during the process.

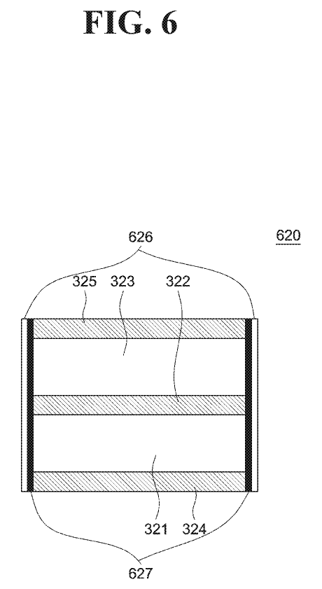

FIG. 6 is a cross-sectional view of a light emitting element according to yet another embodiment of the invention. The light emitting element 620 of FIG. 6 is a vertical type light emitting element like the light emitting element 320 of FIG. 3, and only a passivation film 626 and a light shielding layer 627 are different from the light emitting element 320 of FIG. 3, but other components are substantially the same, thus redundant descriptions will be omitted or briefly given.

Referring to FIG. 6, the light shielding layer 627 may be disposed to surround the first semiconductor layer 321, the light emitting layer 322, the second semiconductor layer 323, the first electrode 324, and the second electrode 325.

The light shielding layer 627 may be disposed on the side surface of the light emitting element 620 to absorb non-uniform light emitted to the side surface. For example, the outer surface of the light emitting element 620 may be formed differently for each light emitting element 620 due to a process or the like. Accordingly, in the outer region of the light emitting element 620, light emitted may vary for each light emitting element 620. In particular, the light emitted from the side surface may have different controllability compared to front light. Therefore, the light shielding layer 627 may be disposed on the side surface in the outer area of the light emitting element 620 to absorb non-uniform light emitted from the side surface, thereby helping improve uniformity in the light emitting characteristics of the light emitting element 620. The light shielding layer 627 may also be disposed to cover at least a portion of the side surface of the light emitting layer 322, but is not limited thereto. For example, the light shielding layer 627 may be disposed to extend to enclose at least a portion of side surfaces of the first semiconductor layer 321, the second semiconductor layer 323, the first electrode 324, and the second electrode 325 as well as the light emitting layer 322.

The passivation film 626 may be disposed on the light shielding layer 627 to surround the first semiconductor layer 321, the light emitting layer 322, the second semiconductor layer 323, the first electrode 324, the second electrode 325, and the light shielding layer 627.

The passivation film 626 may be formed of an insulating material to protect the first semiconductor layer 321, the light emitting layer 322, the second semiconductor layer 323, and the light shielding layer 627. For example, the passivation film 626 may be made of translucent epoxy, aluminum oxide (Al₂O₃), silicon oxide (SiOx), or silicon nitride (SiNx), but is not limited thereto.

The light emitting element 620 according to yet another embodiment of the invention may include a light shielding layer 627, which is disposed on a side surface of the light emitting element 620 and includes a black material. Specifically, the light shielding layer 627 may be disposed to cover a side surface of the light emitting layer 322 in an outer region of the light emitting element 620 and absorb non-uniform light emitted to a side surface, thereby making the light emitting characteristics of the light emitting element 620 substantially uniform. For example, the light shielding layer 627 may reduce or minimize a deviation in light emitting characteristics between the plurality of light emitting elements 620. Accordingly, the display device including the light emitting element 620 according to yet another embodiment of the invention may implement a substantially uniform image, and a tiling display device including a plurality of display devices including the light emitting element 620 electrically connected to one another according to yet another embodiment of the invention may also implement a substantially uniform image. Further, the display device including the light emitting element 620 according to yet another embodiment of the invention and the tiling display device including the plurality of display devices connected to one another may provide improved display quality.

In particular, in the light emitting element 620 according to yet another embodiment of the invention, the passivation film 626 may be disposed on the light shielding layer 627. Specifically, the passivation film 626 may be disposed on the light shielding layer 627 to surround the light shielding layer 627 as well as the first semiconductor layer 321, the light emitting layer 322, the second semiconductor layer 323, the first electrode 324, and the second electrode 325. Accordingly, the passivation film 626 may protect the light shielding layer 627, and it may be possible to reduce or minimize the separation of the light shielding layer 627 or the penetration of impurities into the light shielding layer 627 during the process.

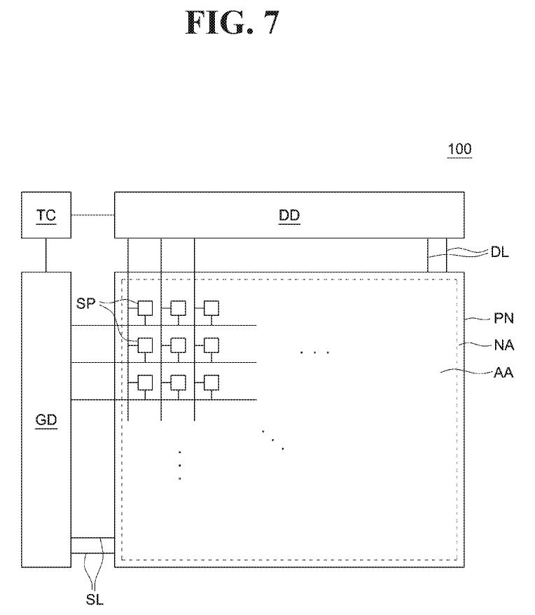

Hereinafter, a display device 100 according to an embodiment of the invention including a light emitting element 120 will be described with reference to FIGS. 7 to 9.

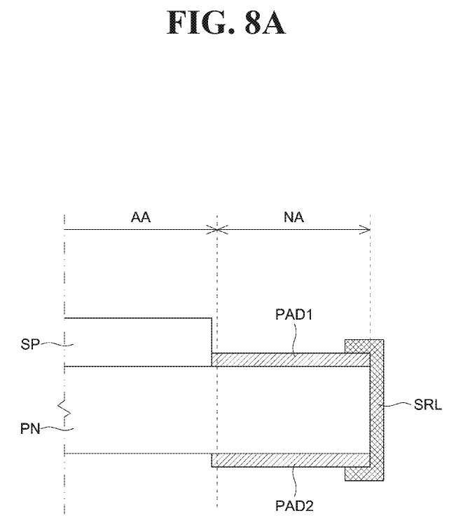

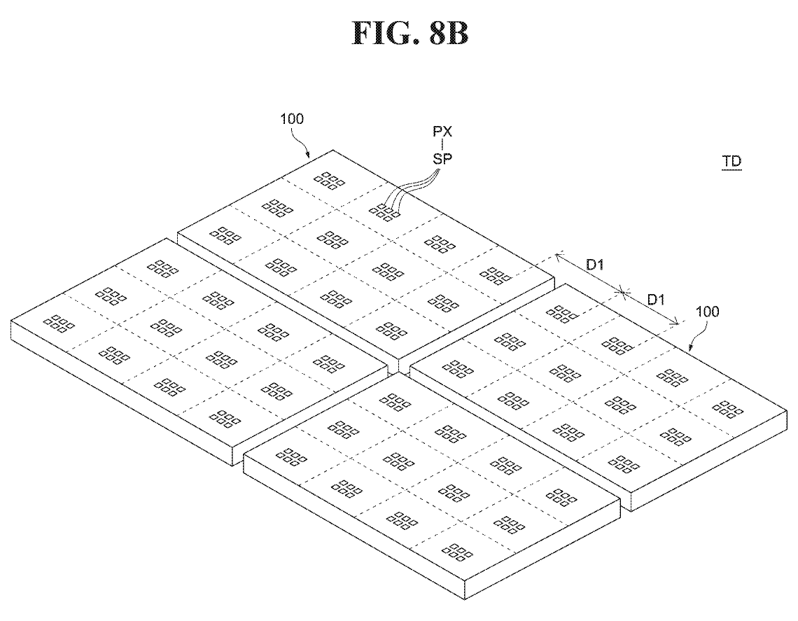

FIG. 7 is a schematic block diagram of a display device according to an embodiment of the invention. FIG. 8A is a partial cross-sectional view of a display device according to an embodiment of the invention. FIG. 8B is a perspective view of a tiling display device according to an embodiment of the invention. In FIG. 7, for the convenience of description, among various components of the display device 100, only a display panel PN, a gate driver GD, a data driver DD, and a timing controller TC are illustrated.

Referring to FIG. 7, the display device 100 includes a display panel PN including a plurality of sub-pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 7 illustrates that one gate driver GD is disposed to be spaced apart from one side of the display panel PN. However, the number and arrangement of the gate drivers GD are not limited thereto. For example, the gate driver GD may be disposed to be spaced apart from two opposite sides of the display panel PN, without being limited thereto.

The data driver DD converts image data input from the timing controller TC into a data voltage using a reference gamma voltage according to a plurality of data control signals provided from the timing controller TC. The data driver DD may supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal, without being limited thereto. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub-pixels SP. In the display panel PN, the plurality of scan lines SL and the plurality of data lines DL intersect each other, and each of the plurality of sub-pixels SP is electrically connected to the scan line SL and the data line DL. In addition, although not illustrated in the drawings, each of the plurality of sub-pixels SP may be electrically connected to a high potential power line, a low potential power line, a reference line, and the like.

In the display panel PN, an active area AA and a non-active area NA extending from the active area AA may be defined.

The active area AA is an area in which images are displayed in the display device 100. In the active area AA, a plurality of sub-pixels SP constituting a plurality of pixels and a circuit for driving the plurality of sub-pixels SP may be disposed. The plurality of sub-pixels SP is a minimum unit constituting the active area AA, and n sub-pixels SP may form one pixel. For example, n may be an integral equal to or greater than two, without being limited thereto. The n sub-pixels SP forming one pixel may also be configured to emit light of different colors, or at least some of the n sub-pixels SP forming one pixel may be configured to emit light of the same color. In each of the plurality of sub-pixels SP, a light emitting element, a thin film transistor for driving the light emitting element, and the like may be disposed. The plurality of light emitting elements may be differently defined depending on the type of the display panel PN. For example, when the display panel PN is an inorganic light emitting display panel, the light emitting element may be a light emitting diode (LED) or a micro light emitting diode (micro-LED). However, embodiments of the invention are not limited thereto.

In the active area AA, a plurality of signal lines for transmitting various signals to the plurality of sub-pixels SP is disposed. For example, the plurality of signal lines may include a plurality of data lines DL which supplies a data voltage to each of the plurality of sub-pixels SP, a plurality of scan lines SL which supplies a gate voltage to each of the plurality of sub-pixels SP, and the like. The plurality of scan lines SL may extend in one direction in the active area AA and be connected to the plurality of sub-pixels SP, and the plurality of data lines DL may extend in a direction different from the one direction in the active area AA and be connected to the plurality of sub-pixels SP. In addition, in the active area AA, a low potential power line, a high potential power line, and the like may be further disposed, but are not limited thereto.

The non-active area NA is an area where no image is displayed, and in the non-active area NA, a link line and a pad electrode for transmitting a signal to the sub-pixel SP of the active area AA, or a driving IC such as a gate driver IC and a data driver IC may be disposed. For example, the non-active area NA may at least partially surround the active area AA, without being limited thereto. The non-active area NA may also be at least partially invisible from a front side of the display panel PN, for example, by being bent toward a rear side of the display panel PN, without being limited thereto. Further, the entire non-active area NDA may be flat.

A driver such as a gate driver GD, a data driver DD, and a timing controller TC may be electrically connected to the display panel PN in various ways. For example, the gate driver GD may be mounted in the non-active area NA in a gate-in-panel (GIP) manner or mounted between the plurality of sub-pixels SP in the active area AA in a gate-in-active area (GIA) manner. For example, the data driver DD and the timing controller TC are formed in separate flexible film and printed circuit board and may be electrically connected to the display panel PN by bonding the flexible film and the printed circuit board to the pad electrode formed in the non-active area NA of the display panel PN. If the gate driver GD is mounted in the GIP manner and the data driver DD and the timing controller TC transmit signals to the display panel PN through the pad electrode of the non-active area NA, it may be advantageous to secure the area of the non-active area NA for disposing the gate driver GD and the pad electrode, and the bezel may increase.

Alternatively, when the gate driver GD is mounted in the active area AA in the GIA manner and a side line SRL, which electrically connects the signal line on the front surface of the display panel PN to the pad electrode on the rear surface of the display panel PN, is formed to bond the flexible film and the printed circuit board to the rear surface of the display panel PN, the non-active area NA on the front surface of the display panel PN may be reduce or minimized. For example, when the gate driver GD, the data driver DD, and the timing controller TC are electrically connected to the display panel PN as described above, a zero bezel with substantially no bezel may be implemented.

Referring to FIGS. 8A and 8B, in the non-active area NA of the display panel PN, a plurality of pad electrodes for transmitting various signals to the plurality of sub-pixels SP is disposed. For example, a first pad electrode PAD1 for transmitting a signal to the plurality of sub-pixels SP is disposed in the non-active area NA on the front surface of the display panel PN, and a second pad electrode PAD2 electrically connected to a driving component such as a flexible film and a printed circuit board is disposed in the non-active area NA on the rear surface of the display panel PN. For example, only a pad area in which the first pad electrode PAD1 of the non-active area NA is disposed may be formed to a minimum on the front surface of the display panel PN in which an image is displayed.

Although not illustrated in the drawings, various signal lines connected to the plurality of sub-pixels SP, for example, a scan line SL or a data line DL extend from the active area AA to the non-active area NA to be electrically connected to the first pad electrode PAD1.

Further, the side line SRL is disposed along the side surface of the display panel PN. The side line SRL may electrically connect the first pad electrode PAD1 on the front surface of the display panel PN and the second pad electrode PAD2 on the rear surface of the display panel PN. Therefore, a signal from the driving component on the rear surface of the display panel PN may be transmitted to the plurality of sub-pixels SP through the second pad electrode PAD2, the side line SRL, and the first pad electrode PAD1. Accordingly, a signal transmission path is formed from the front surface to the side surface and the rear surface of the display panel PN to reduce or minimize the area of the non-active area NA on the front surface of the display panel PN.

Further, referring to FIG. 8B, a tiling display device TD having a large screen may be implemented by electrically connecting a plurality of display devices. In this case, as illustrated in FIG. 8A, when the tiling display device TD is implemented using a display device 100 with a minimized bezel, a seam area in which an image between the display device 100 and the display device 100 is not displayed is reduced or minimized to improve the display quality.

For example, the plurality of sub-pixels SP may form one pixel PX, and an interval D1 between an outermost pixel PX of one display device 100 and an outermost pixel PX of another display device 100 adjacent to the one display device 100 may be implemented to be equal to an interval D1 between pixels in one display device 100. Accordingly, the distance D1 between pixels between the display device 100 and the display device 100 is constantly configured to reduce or minimize the seam area.

However, FIGS. 8A and 8B are illustrative so that the display device according to embodiments of the invention may be a general display device with a bezel, without being limited thereto.

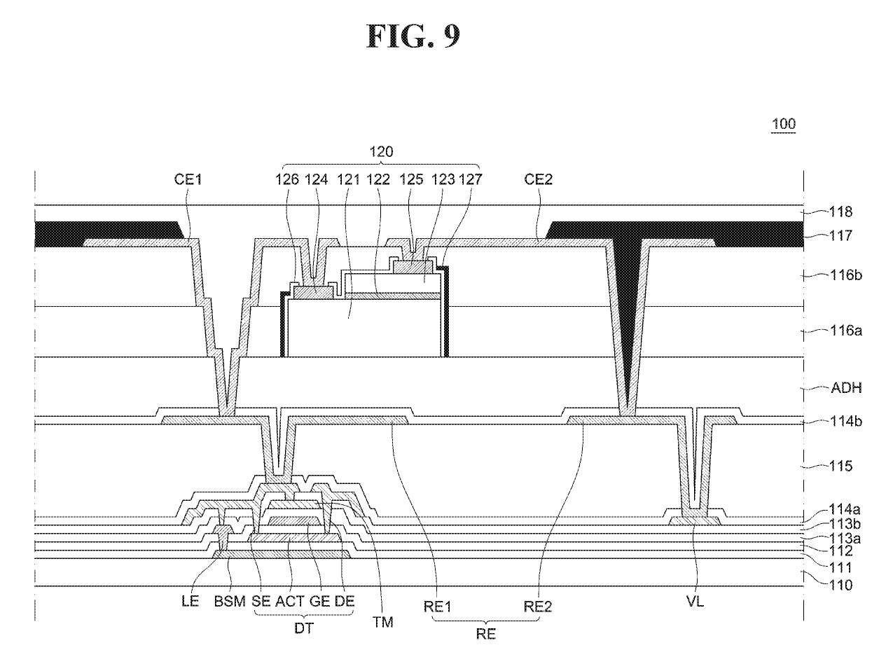

FIG. 9 is a cross-sectional view of a display device according to an embodiment of the invention.

Referring to FIG. 9, a display device 100 according to embodiments of the invention may include a substrate 110, a buffer layer 111, a gate insulating layer 112, a first interlayer insulating layer 113a, a second interlayer insulating layer 113b, a first passivation layer 114a, a second passivation layer 114b, an overcoating layer 115, an adhesive layer ADH, a first planarization layer 116a, a second planarization layer 116b, a bank 117, a protective layer 118, a driving transistor DT, a light emitting element 120, a reflective electrode RE, a bottom shield layer BSM, an auxiliary electrode LE, an intermediate electrode TM, a first connection electrode CE1, a second connection electrode CE2, and a power line VL. Embodiments of the invention are not limited thereto. For example, at least one of the above-mentioned components may be omitted depending on the design, and at least one additional component may be further included, without being limited thereto.

The substrate 110 is a component for supporting various components included in the display device 100 and may be formed of an insulating material. For example, the substrate 110 may be formed of glass, resin, or the like, without being limited thereto. In addition, the substrate 110 may include polymer or plastic, or may be formed of a material having flexibility. However, embodiments of the invention are not limited thereto. For example, the substrate 110 may be formed of a rigid material, and may also be formed of a transparent material or an opaque material, without being limited thereto.

A bottom shield layer BSM may be disposed at each of the plurality of sub-pixels SP on the substrate 110. The bottom shield layer BSM blocks light incident onto an active layer ACT of the driving transistor DT to be described below, below the substrate 110. Light incident on the active layer ACT of the driving transistor DT is blocked by the bottom shield layer BSM to reduce or minimize a leakage current. For example, the bottom shield layer BSM may be omitted depending on the design. The bottom shield layer BSM may also be floated, or may be supplied with a constant voltage, without being limited thereto.

A buffer layer 111 may be disposed on the substrate 110 and the bottom shield layer BSM. The buffer layer 111 may reduce penetration of moisture or impurities through the substrate 110. For example, the buffer layer 111 may be configured as a single layer or multilayer made of silicon oxide (SiOx) or silicon nitride (SiNx). However, embodiments of the invention are not limited thereto. The buffer layer 111 may be omitted depending on the type of substrate 110 or the type of transistor, without being limited thereto.

The driving transistor DT may be disposed on the buffer layer 111. The driving transistor DT includes an active layer ACT, a gate electrode GE, a source electrode SE, and a drain electrode DE.

The active layer ACT may be disposed on the buffer layer 111. The active layer ACT may be formed of a semiconductor material such as an oxide semiconductor, amorphous silicon, polysilicon, compound semiconductor, oxide semiconductor, etc., but is not limited thereto.

The gate insulating layer 112 may be disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), without being limited thereto.

The gate electrode GE may be disposed on the gate insulating layer 112. The gate electrode GE may be configured by a conductive material such as copper (Cu), aluminum (Al), molybdenum (Mo), nickel (Ni), titanium (Ti), chromium (Cr), or an alloy thereof, without being limited thereto.

A first interlayer insulating layer 113a and a second interlayer insulating layer 113b may be disposed on the gate electrode GE. In the gate insulating layer 112, the first interlayer insulating layer 113a, and the second interlayer insulating layer 113b, a contact hole through which the source electrode SE and the drain electrode DE are electrically connected to the active layer ACT is formed. The first interlayer insulating layer 113a and the second interlayer insulating layer 113b are insulating layers for protecting components disposed below the first interlayer insulating layer 113a and the second interlayer insulating layer 113b. The first interlayer insulating layer 113a and the second interlayer insulating layer 113b may be configured by a single layer or a multi-layer of silicon oxide (SiOx) or silicon nitride (SiNx), without being limited thereto.

The source electrode SE and the drain electrode DE, which are electrically connected to the active layer ACT, may be disposed on the second interlayer insulating layer 113b. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Although it has been described in the foregoing embodiments of the invention that only a plurality of insulating layers such as the first interlayer insulating layer 113a and the second interlayer insulating layer 113b may be disposed between the gate electrode GE and the source electrode SE and the drain electrode DE, a single insulating layer may be disposed between the gate electrode GE and the source electrode SE and the drain electrode DE, but without being limited thereto.

Further, although it is not illustrated in the drawing, the pixel circuit may further include a switching transistor, a sensing transistor, a light emitting control transistor, etc. in addition to the driving transistor DT, but without being limited thereto.

The intermediate electrode TM may be disposed on the first interlayer insulating layer 113a, without being limited thereto. The intermediate electrode TM may be disposed to overlap the gate electrode GE of the driving transistor DT with the first interlayer insulating layer 113a interposed therebetween to form a capacitor together with the gate electrode GE of the driving transistor DT. However, embodiments of the invention are not limited thereto. For example, a capacitor may be provided to not overlap with the gate electrode GE of the driving transistor DT. As another example, one of the capacitor electrodes may also be electrically connected with the gate electrode GE of the driving transistor DT, while being spaced apart from the gate electrode GE of the driving transistor DT, without being limited thereto.

The auxiliary electrode LE may be disposed on the gate insulating layer 112, without being limited thereto. The auxiliary electrode LE is an electrode which electrically connects the bottom shield layer BSM under the buffer layer 111 to any one of the source electrode SE of the driving transistor DT and the drain electrode DE of the driving transistor DT on the second interlayer insulating layer 113b. For example, the bottom shield layer BSM may be electrically connected to any one of the source electrode SE and the drain electrode DE of the driving transistor DT through the auxiliary electrode LE not to operate as a floating gate. Therefore, fluctuation of a threshold voltage of the driving transistor DT caused by the floated bottom shield layer BSM may be reduced or minimized. Although the drawing illustrates that the bottom shield layer BSM is electrically connected to the source electrode SE of the driving transistor DT, the bottom shield layer BSM may be electrically connected to the drain electrode DE of the driving transistor DT, without being limited thereto. Also, the auxiliary electrode LE may be omitted depending on the design.

The power line VL may be disposed on the second interlayer insulating layer 113b, without being limited thereto. The power line VL is electrically connected to the light emitting element 120 together with the driving transistor DT to allow the light emitting element 120 to emit light. The power line VL may be configured by a conductive material such as copper (Cu), aluminum (Al), molybdenum (Mo), nickel (Ni), titanium (Ti), chrome (Cr), or an alloy thereof, but is not limited thereto.

A first passivation layer 114a may be disposed on the driving transistor DT and the power line VL. The first passivation layer 114a may protect the driving transistor DT and the power line VL from penetration of moisture or impurities. For example, the first passivation layer 114a may be configured by a single layer or a multi-layer of silicon oxide (SiOx) or silicon nitride (SiNx), but is not limited thereto. The first passivation layer 114a may be omitted depending on the type of substrate 110 or the type of transistor, without being limited thereto.

The overcoating layer 115 may be disposed on the first passivation layer 114a. The overcoating layer 115 may planarize an upper portion of the substrate 110 on which the driving transistor DT is disposed. The overcoating layer 115 may be configured by a single layer or a multilayer, and for example, may be formed of photoresist or an acrylic organic material, without being limited thereto.

For example, a plurality of reflective electrodes RE spaced apart from each other may be disposed on the overcoating layer 115. The plurality of reflective electrodes RE electrically connects the light emitting element 120 to the power line VL and the driving transistor DT and may serve as a reflective plate that reflects light emitted from the light emitting element 120 to an upper portion of the light emitting element 120. Embodiments of the invention are not limited thereto. For example, the reflective electrode RE may only serve to electrically connect the light emitting element 120 to the power line VL or the driving transistor DT, but may not reflect light emitted from the light emitting element 120. Alternatively, the reflective electrode RE may not serve to electrically connect the light emitting element 120 to the power line VL or the driving transistor DT. Also, the reflective electrode RE may be omitted depending on the design. The plurality of reflective electrodes RE is formed of a conductive material having high reflectivity to reflect light emitted from the light emitting element 120 toward the upper portion of the light emitting element 120. Accordingly, the plurality of reflective electrodes RE may include various conductive layers in consideration of light reflection efficiency and resistance. For example, the reflective electrodes RE may use an opaque conductive layer such as silver (Ag), aluminum (Al), molybdenum (Mo), titanium (Ti), or an alloy thereof and a transparent conductive layer such as indium tin oxide (ITO), but the structure and material of the reflective electrode RE are not limited thereto.

The plurality of reflective electrodes RE may include a first reflective electrode RE1 and a second reflective electrode RE2. The first reflective electrode RE1 may electrically connect the driving transistor DT and the light emitting element 120. The first reflective electrode RE1 may be electrically connected to the source electrode SE or the drain electrode DE of the driving transistor DT through a contact hole formed in the first passivation layer 114a and the overcoating layer 115. Further, the first reflective electrode RE1 may be electrically connected to the first electrode 124 of the light emitting element 120 through the first connection electrode CE1.

The second reflective electrode RE2 may electrically connect the power line VL and the light emitting element 120. The second reflective electrode RE2 may be electrically connected to the power line VL through a contact hole formed in the first passivation layer 114a and the overcoating layer 115, and may be electrically connected to the second electrode 125 of the light emitting element 120 through a second connection electrode CE2 to be described below.

The second passivation layer 114b may be disposed on the plurality of reflective electrodes RE. The second passivation layer 114b may protect the plurality of reflective electrodes RE from penetration of moisture or impurities. For example, the second passivation layer 114b may be configured by a single layer or a multilayer of silicon oxide (SiOx) or silicon nitride (SiNx), without being limited thereto.

An adhesive layer ADH may be disposed on the second passivation layer 114b. The adhesive layer ADH may be formed on the front surface of the substrate 110 to fix the light emitting element 120 disposed on the adhesive layer ADH. For example, the adhesive layer ADH may be formed of a photocurable or thermosetting adhesive material that may be cured by light or heat, without being limited thereto. For example, the adhesive layer ADH may be formed of an acrylic material including a photosensitizer, but is not limited thereto.

The plurality of light emitting elements 120 may be disposed in each of the plurality of sub-pixels SP on the adhesive layer ADH. The plurality of light emitting elements 20 are elements which emit light by a current and may include the light emitting elements 120 which emit red light, green light, and blue light and implement various colored light including white by a combination thereof. For example, the plurality of light emitting elements 120 may be a light emitting diode (LED) or a light emitting diode (micro-LED), but embodiments of the invention are not limited thereto. For example, the plurality of light emitting elements 120 may include the light emitting elements 120, which emit light of colors other than red, blue, and green, such as white, yellow, cyan, magenta, without being limited thereto.

The first planarization layer 116a may be disposed on the adhesive layer ADH. The first planarization layer 116a is disposed to enclose a part of side surfaces of the plurality of light emitting elements 120 to fix and protect the plurality of light emitting elements 120. Therefore, the first planarization layer 116a may be electrically in contact with the light shielding layer 127 disposed at the outermost periphery of the light emitting element 120, without being limited thereto. As another example, the first planarization layer 116a may be electrically in contact with the passivation film 126 disposed at the outermost periphery of the light emitting element 120 such as outside of the light shielding layer 127, without being limited thereto. The first planarization layer 116a may also be electrically in contact with a part of the first semiconductor layer 121 exposed by the light shielding layer 127 and the passivation film 126, without being limited thereto. The first planarization layer 116a may be configured as a single layer or multilayer and made of, for example, photoresist or an acrylic-based organic material, but is not limited thereto.

The second planarization layer 116b may be disposed on the first planarization layer 116a. The second planarization layer 116b planarizes an upper portion of the substrate 110 on which the light emitting element 120 is disposed together with the first planarization layer 116a and may fix the light emitting element 120 onto the substrate 110 together with the adhesive layer ADH.

The second planarization layer 116b may also be disposed to surround the light emitting element 120 and may be electrically in contact with the light shielding layer 127 disposed at the outermost periphery of the light emitting element 120, but is not limited thereto. As another example, the second planarization layer 116b may be electrically in contact with the passivation film 126 exposed by the light shielding layer 127 such as on the top of the light emitting element 120, without being limited thereto. The second planarization layer 116b may also be electrically in contact with the passivation film 126 disposed at the outermost periphery of the light emitting element 120 such as outside of the light shielding layer 127, without being limited thereto.

The first connection electrode CE1 may be disposed on the second planarization layer 116b. The first connection electrode CE1 is an electrode which is disposed in each of the plurality of sub-pixels SP to electrically connect the light emitting element 120 and the driving transistor DT. The first connection electrode CE1 may be electrically connected to the first reflective electrode RE1 through a contact hole formed in the first planarization layer 116a, the second planarization layer 116b, the adhesive layer ADH, and the second passivation layer 114b. Accordingly, the first connection electrode CE1 may be electrically connected to any one of the source electrode SE and the drain electrode DE of the driving transistor DT through the first reflective electrode RE1. For example, the first connection electrode CE1 may electrically connect the first electrode 124 of the light emitting element 120 to the source electrode SE of the driving transistor DT, without being limited thereto.

The second connection electrode CE2 may be disposed on the second planarization layer 116b. The second connection electrode CE2 is an electrode for electrically connecting the light emitting element 120 and the power line VL. The second connection electrode CE2 may be electrically connected to the second reflective electrode RE2 through contact holes formed in the first planarization layer 116a, the second planarization layer 116b, the second passivation layer 114b, and the adhesive layer ADH. Accordingly, the second connection electrode CE2 may be electrically connected to the power line VL through the second reflective electrode RE2. For example, the second connection electrode CE2 may electrically connect the second electrode 125 of the light emitting element 120 and the power line VL, but is not limited thereto.

A bank 117 may be disposed on the second planarization layer 116b, the first connection electrode CE1, and the second connection electrode CE2. The bank 117 may be disposed not to overlap the light emitting element 120 to define a light emitting area. For example, the bank 117 may cover edges of the first connection electrode CE1 and the second connection electrode CE2 connected to each light emitting element 120 to define a light emitting area. For example, the bank 117 may divide the plurality of sub-pixels SP. The bank 117 may be formed of an insulating material to insulate the first connection electrode CE1 and the second connection electrode CE2 of adjacent sub-pixels SP from each other. Further, the bank 117 may include a black component having a high light absorption rate to reduce or prevent color mixture between adjacent sub-pixels SP. For example, the bank 117 may be formed of polyimide resin, acrylic resin, or benzocyclobutene (BCB) resin, without being limited thereto. For example, the first connection electrode CE1 and the second connection electrode CE2 of adjacent sub-pixels SP may be spaced apart from each other, with or without the bank 117. The bank 117 may also cover an edge of the first connection electrode CE1 and an edge of the second connection electrode CE2, without being limited thereto. Further, the bank 117 may be omitted depending on the design.

A protective layer 118 may be disposed on the second planarization layer 116b and the bank 117. The protective layer 118 may be disposed to cover an upper surface of the light emitting element 120 to planarize an upper portion of the substrate 110 on which the light emitting element 120 is disposed and fix and protect the light emitting element 120. Therefore, the protective layer 118 may also be referred to as a planarization layer or a capping layer, but is not limited thereto. The protective layer 118 may be configured as a single layer or multilayer and formed of, for example, a photoresist or an acrylic-based organic material, without being limited thereto.

In the display device 100 according to the embodiment of the invention, the light emitting element 120 may be disposed with a light shielding layer 127 including a black material on the side surface of the light emitting element 120 . Specifically, the light shielding layer 127 may be disposed to cover a side surface of the light emitting layer 122 in an outer peripheral area of the light emitting element 120 and absorb light leaking from the side surface of the light emitting layer 122. For example, the light shielding layer 127 is disposed on the side surface of the light emitting element 120 to absorb non-uniform light emitted to the side surface to make the light emitting characteristics of the light emitting element 120 substantially uniform. For example, the light shielding layer 127 may reduce or minimize a deviation in light emitting characteristics between the plurality of light emitting elements 120. Accordingly, the display device 100 according to the embodiment of the invention may implement a substantially uniform image, and the tiling display device TD including a plurality of display devices 100 according to an embodiment of the invention electrically connected to one another may also implement a substantially uniform image. Further, the display device 100 according to the embodiment of the invention and the tiling display device TD including a plurality of display devices 100 electrically connected to one another may provide improved display quality.

FIGS. 7 to 9 illustrate only the display device 100 including the light emitting element 120 of FIG. 1A among the light emitting elements 120 and 120’ according to the embodiment of the invention. However, the display device including the light emitting element 120’ of FIG. 1B may also have substantially the same structure as the display device 100 of FIGS. 7 to 9.

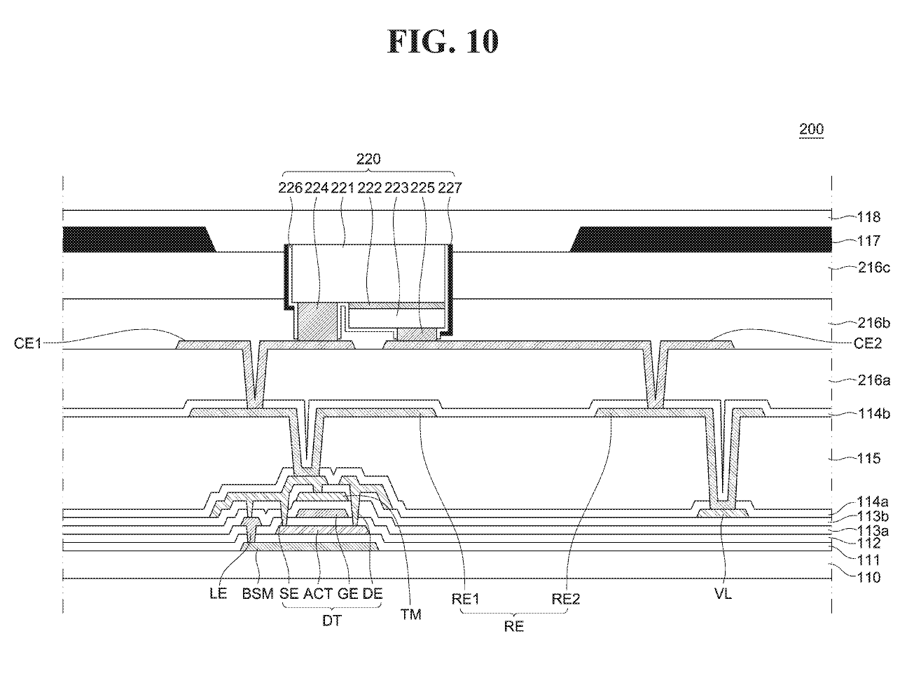

FIG. 10 is a cross-sectional view of a display device according to another embodiment of the invention. Specifically, a display device 200 of FIG. 10 is a display device including the light emitting element 220 of FIG. 2. The display device 200 of FIG. 10 is substantially identical in configuration to the display device 100 of FIGS. 7 to 9, except for a light emitting element 220, a first connection electrode CE1, a second connection electrode CE2, a first planarization layer 216a, a second planarization layer 216b, and a third planarization layer 216c. Therefore, repeated descriptions of the identical components will be omitted or briefly given.

Referring to FIG. 10, a first planarization layer 216a may be disposed on the second passivation layer 114b. The first planarization layer 216a may planarize an upper portion of the substrate 110 on which the driving transistor DT is disposed, together with the overcoating layer 115.

The first connection electrode CE1 and the second connection electrode CE2 may be disposed on the first planarization layer 216a. The first connection electrode CE1 is an electrode, which is disposed in each of the plurality of sub-pixels SP to electrically connect the light emitting element 220 and the driving transistor DT. The first connection electrode CE1 may be electrically connected to the first reflective electrode RE1 through a contact hole formed in the first planarization layer 216a and the second passivation layer 114b. Accordingly, the first connection electrode CE1 may be electrically connected to the source electrode SE of the driving transistor DT through the first reflective electrode RE1. For example, the first connection electrode CE1 may electrically connect the first electrode 224 of the light emitting element 120 to the source electrode SE of the driving transistor DT, without being limited thereto.

The second connection electrode CE2 is an electrode for electrically connecting the light emitting element 220 and the power line VL. The second connection electrode CE2 may be electrically connected to the second reflective electrode RE2 through a contact hole formed in the first planarization layer 216a and the second passivation layer 114b. Accordingly, the second connection electrode CE2 may be electrically connected to the power line VL through the second reflective electrode RE2. For example, the second connection electrode CE2 may electrically connect the second electrode 225 of the light emitting element 220 and the power line VL, without being limited thereto.

A plurality of light emitting elements 220 may be disposed in each of the plurality of sub-pixels SP on the first connection electrode CE1 and the second connection electrode CE2.

The second planarization layer 216b may be disposed on the first connection electrode CE1, the second connection electrode CE2, and the first planarization layer 216a. The second planarization layer 216b is disposed to enclose a part of side surfaces of the plurality of light emitting elements 220, and may fix and protect the plurality of light emitting elements 220. Therefore, the second planarization layer 216b may be electrically in contact with the light shielding layer 227 disposed at the outermost periphery of the light emitting element 220, without being limited thereto.

A third planarization layer 216c may be disposed on the second planarization layer 216b. The third planarization layer 216c planarizes an upper portion of the substrate 110 on which the light emitting element 220 is disposed, together with the first planarization layer 216a and the second planarization layer 216b, and may fix the light emitting element 220 onto the substrate 110. The third planarization layer 216c may also be disposed to surround the light emitting element 220 and may be electrically in contact with the light shielding layer 227 disposed at the outermost periphery of the light emitting element 220, without being limited thereto. For example, the third planarization layer 216c may surround the entirety of the side surface of the light emitting element 220, or may expose a part of the light emitting element 220 such as an upper edge of the light emitting element 220, without being limited thereto. For example, the light shielding layer 227 disposed at the side surface of the light emitting element 220 may be surrounded by the third planarization layer 216c, or at least a portion thereof such as an upper edge may be exposed by the third planarization layer 216c. However, embodiments of the invention are not limited thereto. In some embodiments, the exposed side surface of the light emitting element 220 or the exposed light shielding layer 227 may be covered by the protective layer 118, without being limited thereto.

In the display device 200 according to another embodiment of the invention, the light emitting element 220 may be disposed with a light shielding layer 227 including a black material on the side surface of the light emitting element 220. Specifically, the light shielding layer 227 is disposed to cover the side surface of the light emitting layer 222 in the outer peripheral area of the light emitting element 220 and absorb non-uniform light emitted to the side surface to make the light emitting characteristics of the light emitting element 220 substantially uniform. For example, the light shielding layer 227 may reduce or minimize a deviation in light emitting characteristics between the plurality of light emitting elements 220. Accordingly, the display device 200 according to another embodiment of the invention may implement a substantially uniform image. Accordingly, the tiling display device TD including a plurality of display devices 200 electrically connected to one another according to another embodiment of the invention may also implement a substantially uniform image. Further, the display quality of the display device 200 according to another embodiment of the invention and the tiling display device TD including a plurality of display devices 200 electrically connected to one another may provide improved display quality.

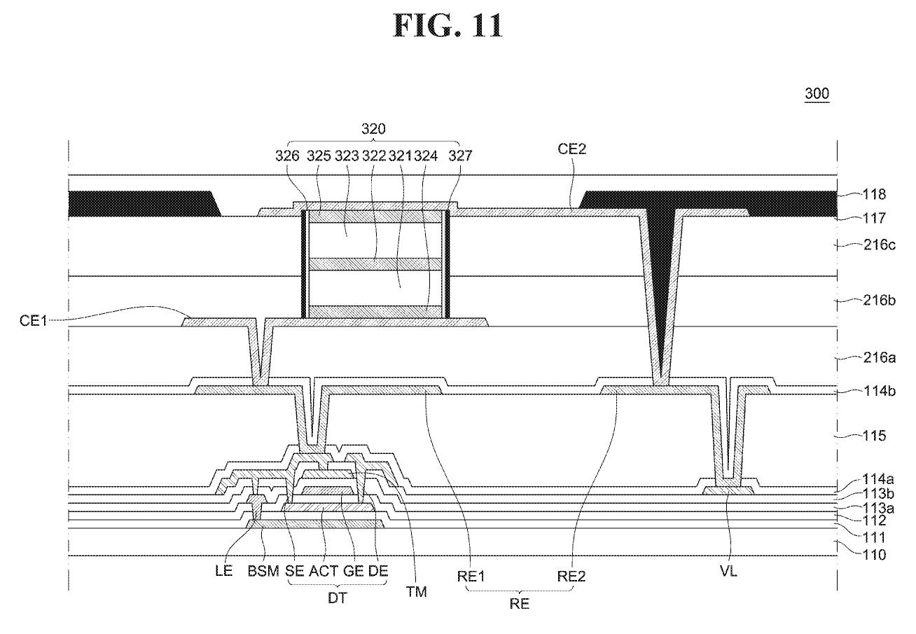

FIG. 11 is a cross-sectional view of a display device according to yet another embodiment of the invention. Specifically, a display device 300 of FIG. 11 is the display device including the light emitting element 320 of FIG. 3. The only difference between a display device 300 of FIG. 11 and the display device 300 of FIG. 10 is a light emitting element 320 and a second connection electrode CE2, but other components are substantially the same, so that a redundant description will be omitted or briefly given.

Referring to FIG. 11, a plurality of light emitting elements 320 may be disposed in each of the plurality of sub-pixels SP on the first connection electrode CE1.

The second connection electrode CE2 may be disposed on the third planarization layer 216c. The second connection electrode CE2 is an electrode for electrically connecting the light emitting element 320 and the power line VL. The second connection electrode CE2 may be electrically connected to the second reflective electrode RE2 through contact holes formed in the first planarization layer 216a, the second planarization layer 216b, the third planarization layer 216c, and the second passivation layer 114b. Accordingly, the second connection electrode CE2 may be electrically connected to the power line VL through the second reflective electrode RE2. For example, the second connection electrode CE2 may electrically connect the second electrode 325 of the light emitting element 320 and the power line VL, but embodiments of the invention are not limited thereto.

In the display device 300 according to yet another embodiment of the invention, the light emitting element 320 may be disposed with a light shielding layer 327 including a black material on a side surface of the light emitting element 320. Specifically, the light shielding layer 327 may be disposed to cover a side surface of the light emitting layer 322 in an outer peripheral area of the light emitting element 220 and absorb non-uniform light emitted to a side surface, thereby making the light emitting characteristics of the light emitting element 320 substantially uniform. For example, the light shielding layer 327 may reduce or minimize a deviation in light emitting characteristics between the plurality of light emitting elements 320. Accordingly, the display device 300 according to yet another embodiment of the invention may implement a substantially uniform image. Accordingly, the tiling display device TD including a plurality of display devices 300 electrically connected to one another according to yet another embodiment of the invention may also implement a substantially uniform image. Accordingly, the display device 300 according to yet another embodiment of the invention and the tiling display device TD including a plurality of display devices 300 electrically connected to one another may be provide improved display quality.

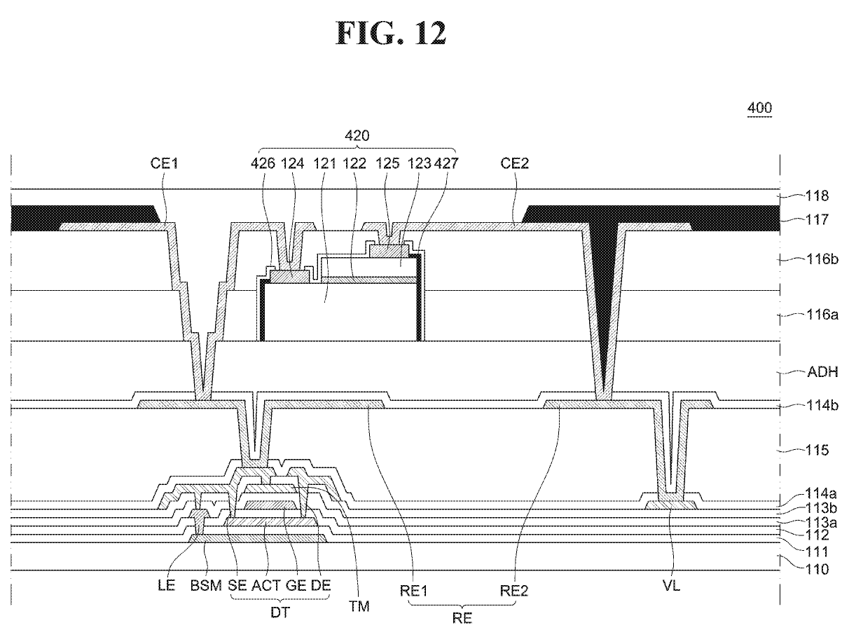

FIG. 12 is a cross-sectional view of a display device according to yet another embodiment of the invention. Specifically, a display device 400 of FIG. 12 is the display device including the light emitting element 420 of FIG. 4. The only difference between a display device 400 of FIG. 12 and the display device 100 of FIGS. 7 to 9 is a light emitting element 420, but other components are substantially the same, so that a redundant description will be omitted or briefly given.

Referring to FIG. 12, as described above with reference to FIG. 4, the passivation film 426 may be disposed on the light shielding layer 427 to surround the first semiconductor layer 121, the light emitting layer 122, the second semiconductor layer 123, the first electrode 124, the second electrode 125, and the light shielding layer 427.

Therefore, the first planarization layer 116a and the second planarization layer 116b, which are disposed to surround the light emitting element 420, may be disposed to be spaced apart from the light shielding layer 427 with respect to the passivation film 426, but are not limited thereto.

In the display device 400 according to yet another embodiment of the invention, the light emitting element 420 may be disposed with a light shielding layer 427 including a black material on a side surface of the light emitting element 420. Specifically, the light shielding layer 427 is disposed to cover the side surface of the light emitting layer 122 in the outer peripheral area of the light emitting element 420 and absorb non-uniform light emitted to the side surface to make the light emitting characteristic of the light emitting element 420 substantially uniform. For example, the light shielding layer 427 may reduce or minimize a deviation in light emitting characteristics between the plurality of light emitting elements 420. Accordingly, the display device 400 according to yet another embodiment of the invention may implement a substantially uniform image. Accordingly, the tiling display device TD including a plurality of display devices 400 according to yet another embodiment of the invention electrically connected to one another may also implement a substantially uniform image. Further, the display device 400 according to yet another embodiment of the invention and the tiling display device TD including a plurality of display devices 400 electrically connected to one another may provide improved display quality.

In particular, in the display device 400 according to yet another embodiment of the invention, the passivation film 426 of the light emitting element 420 may be disposed on the light shielding layer 427. Specifically, the passivation film 426 may be disposed on the light shielding layer 427 to surround the light shielding layer 127 as well as the first semiconductor layer 121, the light emitting layer 122, the second semiconductor layer 123, the first electrode 124, and the second electrode 125. Accordingly, the passivation film 426 may protect the light shielding layer 427, and it may be possible to reduce or minimize the separation of the light shielding layer 427 or the penetration of impurities into the light shielding layer 427 during the process.

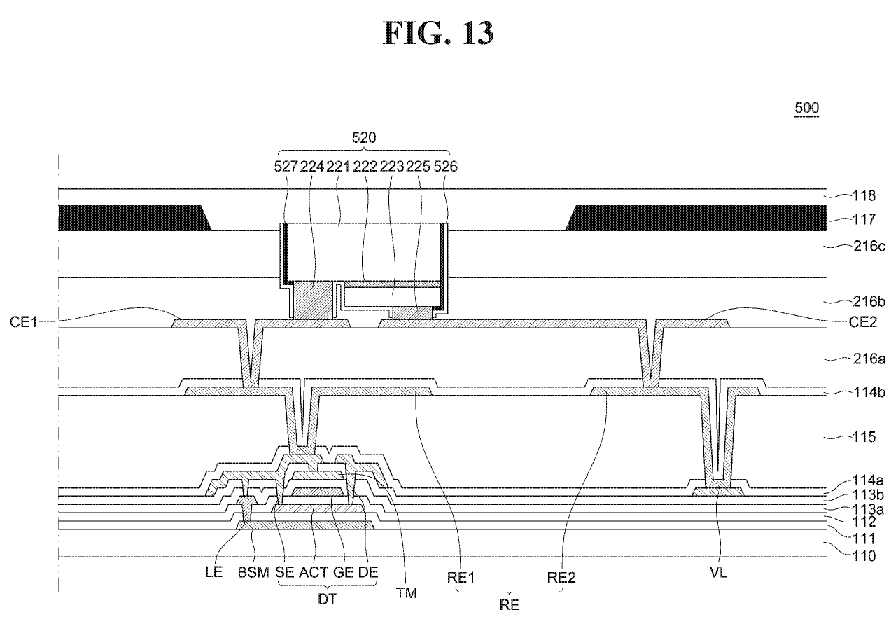

FIG. 13 is a cross-sectional view of a display device according to yet another embodiment of the invention. Specifically, a display device 500 of FIG. 13 is the display device including the light emitting element 520 of FIG. 5. The only difference between the display device 500 of FIG. 13 and the display device 200 of FIG. 10 is a light emitting element 520, but other components are substantially the same, so that a redundant description will be omitted or briefly given.

Referring to FIG. 13, as described above with reference to FIG. 5, the passivation film 526 may be disposed on the light shielding layer 527 to surround the first semiconductor layer 221, the light emitting layer 222, the second semiconductor layer 223, the first electrode 224, the second electrode 225, and the light shielding layer 527.

Therefore, the second planarization layer 216b and the third planarization layer 216c disposed to surround the light emitting element 520 may be disposed to be spaced apart from the light shielding layer 527 with respect to the passivation film 526, without being limited thereto.

In the display device 500 according to yet another embodiment of the invention, the light emitting element 520 may be disposed with a light shielding layer 527 including a black material on the side surface of the light emitting element 520. Specifically, the light shielding layer 527 is disposed to cover the side surface of the light emitting layer 222 in the outer peripheral area of the light emitting element 520 and absorb non-uniform light emitted to the side surface to make the light emitting characteristics of the light emitting element 520 substantially uniform. For example, the light shielding layer 527 may reduce or minimize a deviation in light emitting characteristics between the plurality of light emitting elements 520. Accordingly, the display device 500 according to yet another embodiment of the invention may implement a substantially uniform image. Accordingly, the tiling display device TD including a plurality of display devices 500 electrically connected to one another according to yet another embodiment of the invention may also implement a substantially uniform image. Accordingly, the display device 500 according to yet another embodiment of the invention and the tiling display device TD including a plurality of display devices 500 electrically connected to one another may provide improved display quality.

In particular, in the display device 500 according to yet another embodiment of the invention, the passivation film 526 of the light emitting element 520 may be disposed on the light shielding layer 527. Specifically, the passivation film 526 may be disposed on the light shielding layer 527 to surround the light shielding layer 527 as well as the first semiconductor layer 221, the light emitting layer 222, the second semiconductor layer 223, the first electrode 224, and the second electrode 225. Accordingly, the passivation film 526 may protect the light shielding layer 527, and it may be possible to reduce or minimize the separation of the light shielding layer 527 or the penetration of impurities into the light shielding layer 527 during the process.

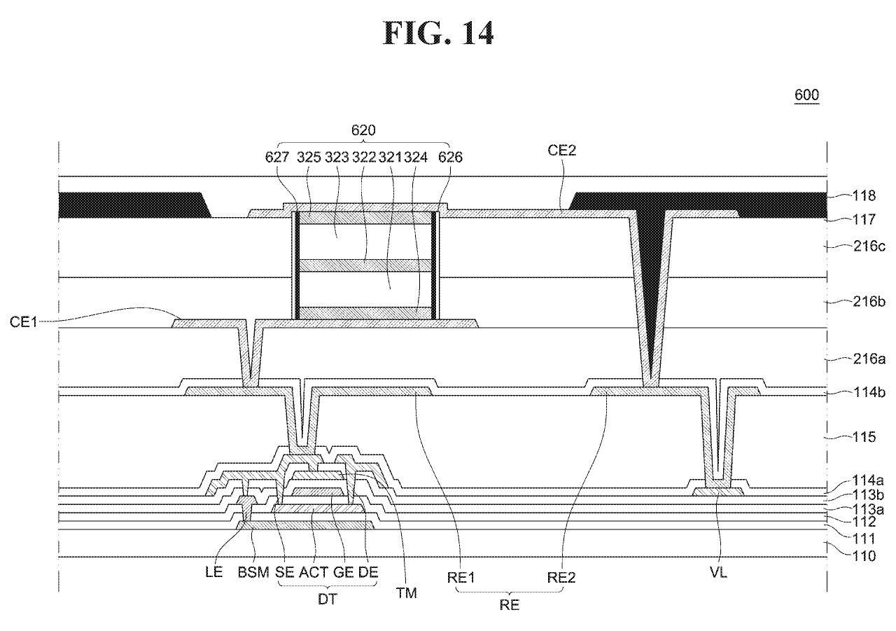

FIG. 14 is a cross-sectional view of a display device according to yet another embodiment of the invention. Specifically, a display device 600 of FIG. 14 is the display device including the light emitting element 620 of FIG. 6. The only difference between a display device 600 of FIG. 14 and the display device 300 of FIG. 11 is a light emitting element 620, but other components are substantially the same, so that a redundant description will be omitted or briefly given.

Referring to FIG. 14, as described above with reference to FIG. 6, the passivation film 626 may be disposed on the light shielding layer 627 to surround the first semiconductor layer 321, the light emitting layer 322, the second semiconductor layer 323, the first electrode 324, the second electrode 325, and the light shielding layer 627.

Therefore, the second planarization layer 216b and the third planarization layer 216c, which are disposed to enclose the light emitting element 620, may be disposed to be spaced apart from the light shielding layer 627 based on the passivation film 626, but embodiments of the invention are not limited thereto.

In the display device 600 according to yet another exemplary embodiment of the present disclosure, the light emitting element 620 may be disposed with a light shielding layer 627 including a black material on the side surface of the light emitting element 620. Specifically, the light shielding layer 627 may be disposed to cover a side surface of the light emitting layer 322 in an outer region of the light emitting element 620 and absorb non-uniform light emitted to a side surface, thereby making the light emitting characteristics of the light emitting element 620 substantially uniform. For example, the light shielding layer 627 may reduce or minimize a deviation in light emitting characteristics between the plurality of light emitting elements 620. Accordingly, the display device 600 according to yet another embodiment of the invention may implement a substantially uniform image, and the tiling display device TD including a plurality of display devices 600 according to yet another exemplary embodiment of the invention electrically connected to one another may also implement a substantially uniform image. Further, the display device 600 according to yet another embodiment of the invention and the tiling display device TD including a plurality of display devices 600 electrically connected to one another may provide improved display quality.

In particular, in the display device 600 according to yet another embodiment of the invention, the passivation film 626 of the light emitting element 620 may be disposed on the light shielding layer 627. Specifically, the passivation film 626 may be disposed on the light shielding layer 627 to surround the light shielding layer 627 as well as the first semiconductor layer 321, the light emitting layer 322, the second semiconductor layer 323, the first electrode 324, and the second electrode 325. Accordingly, the passivation film 626 may protect the light shielding layer 627, and it may be possible to reduce or minimize the separation of the light shielding layer 627 or the penetration of impurities into the light shielding layer 627 during the process.

According to embodiments of the invention, the light emitting element may have uniform light emitting characteristics.

According to embodiments of the invention, the deviation of light emitting characteristics between light emitting elements is minimized so that the display device displays a uniform image.

According to embodiments of the invention, it is possible to improve display quality of the display device.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting element comprising:
a first semiconductor layer;
a second semiconductor layer disposed on one side of the first semiconductor layer;
a light emitting layer disposed between the first semiconductor layer and the second semiconductor layer; and
a light shielding layer enclosing at least a portion of a side surface of the light emitting layer and including a light absorbing material.

2. The light emitting element of claim 1, further comprising:
a passivation film enclosing at least a portion of side surfaces of the first semiconductor layer, the light emitting layer, and the second semiconductor layer,
wherein the light shielding layer is disposed on the passivation film.

3. The light emitting element of claim 2, wherein a portion of the passivation film is exposed by the light shielding layer.

4. The light emitting element of claim 3, further comprising:
a first electrode electrically in contact with the first semiconductor layer; and
a second electrode electrically in contact with the second semiconductor layer,
wherein a portion of the passivation film at a side surface of the first electrode and a side surface of the second electrode is exposed by the light shielding layer.

5. The light emitting element of claim 1, further comprising:
a passivation film disposed around at least a portion of side surfaces of the first semiconductor layer, the light emitting layer, the second semiconductor layer, and the light shielding layer.

6. The light emitting element of claim 5, wherein the passivation film is disposed around the entirety of the side surface of the light shielding layer.

7. The light emitting element of claim 6, further comprising:
a first electrode electrically in contact with the first semiconductor layer; and
a second electrode electrically in contact with the second semiconductor layer,
wherein the passivation film covers an end of the light shielding layer at a side surface of the first electrode and a side surface of the second electrode.

8. The light emitting element of claim 1, wherein a portion of a side surface of the first semiconductor layer that faces away the light emitting layer is exposed by the light shielding layer.

9. The light emitting element of claim 3, wherein a portion of the side surface of the first semiconductor layer that faces away the light emitting layer is exposed by the light shielding layer and the passivation film.

10. The light emitting element of claim 5, wherein a portion of the side surface of the first semiconductor layer that faces away the light emitting layer is exposed by the light shielding layer and the passivation film.

11. The light emitting element of claim 9, wherein an end of the light shielding layer and an end of the passivation film at a side surface of the first semiconductor layer are aligned.

12. The light emitting element of claim 1, wherein the light shielding layer includes a black material.

13. The light emitting element of claim 1, wherein the light shielding layer covers at least a portion of side surfaces of the first semiconductor layer and the second semiconductor layer.

14. The light emitting element of claim 13, further comprising:
a first electrode disposed on the first semiconductor layer exposed by the second semiconductor layer and the light emitting layer; and
a second electrode disposed on the second semiconductor layer,
wherein the light shielding layer covers at least a portion of side surfaces of the first electrode and the second electrode, and
wherein the light shielding layer is disposed on any one side surface of the first electrode and any one side surface of the second electrode.

15. The light emitting element of claim 13, further comprising:
a first electrode disposed below the first semiconductor layer exposed by the second semiconductor layer and the light emitting layer; and
a second electrode disposed below the second semiconductor layer,
wherein the light shielding layer covers at least a portion of side surfaces of the first electrode and the second electrode, and
wherein the light shielding layer is disposed on any one side surface of the first electrode and any one side surface of the second electrode.

16. The light emitting element of claim 13, further comprising:
a first electrode disposed below the first semiconductor layer below the second semiconductor layer; and
a second electrode disposed on the second semiconductor layer,
wherein the light shielding layer covers at least a portion of side surfaces of the first electrode and the second electrode, and
wherein the light shielding layer is disposed on both side surfaces of the first electrode and both side surfaces of the second electrode.

17. A display device, comprising:
a substrate on which a plurality of sub-pixels is defined;
a plurality of transistors disposed on the substrate; and
a plurality of light emitting elements of claim 1 disposed in each of the plurality of sub- pixels on the substrate.

18. The display device of claim 17, further comprising:
a planarization layer disposed on the plurality of transistors and surrounding the plurality of light emitting elements,
wherein the light shielding layer is electrically in contact with the planarization layer.

19. A tiling display device, comprising a plurality of display devices of claim 17.
